(19) United States
(12) Patent Application Publication
(10) Pub. No.: US 2022/0131039 A1
(43) Pub. Date: Apr. 28, 2022

(54) MICRO LIGHT-EMITTING DIODE

(71) Applicant: EPILEDS TECHNOLOGIES, INC., Tainan City (TW)

(72) Inventors: Li-Wei HUNG, Tainan City (TW); Hsin-Liang YEH, Tainan City (TW); Wei-Chen CHIEN, Tainan City (TW); Ming-Sen HSU, Tainan City (TW)

(21) Appl. No.: 17/134,547

(22) Filed: Dec. 28, 2020

(30) Foreign Application Priority Data
Oct. 22, 2020 (TW) 109136749

(51) Int. Cl. H01L 33/22; H01L 27/15; H01L 33/38

(52) U.S. Cl. CPC H01L 33/22; H01L 33/382; H01L 27/156

(57) ABSTRACT

A micro light-emitting diode includes an epitaxial structure, an insulation layer, a first electrode, and a second electrode. The epitaxial structure includes a first semiconductor layer, a light-emitting layer, and a second semiconductor layer. The epitaxial structure has a cavity penetrating the second semiconductor layer and the light-emitting layer and exposing a portion of the first semiconductor layer. The insulation layer covers the epitaxial structure, and a side surface and a bottom surface of the cavity. The insulation layer has a first hole exposing a portion of the second semiconductor layer, and a second hole exposing a portion of the bottom surface. The first electrode covers the exposed portion of the bottom surface. The second electrode covers the exposed portion of the second semiconductor layer and is distant from the first electrode. The cavity is distant from an edge of the micro LED.

### RELATED APPLICATIONS

This application claims priority to Taiwan Application Serial Number 109136749, filed Oct. 22, 2020, which is herein incorporated by reference.

### BACKGROUND

### Field of Invention

The present disclosure relates to a light-emitting device, and more particularly, to a micro light-emitting diode (micro LED).

### Description of Related Art

Typically, in manufacturing a micro LED, an epitaxial structure is firstly grown on a growth substrate, and contact electrodes are disposed on the epitaxial structure. Then, a temporary sub-mount is bonded on the contact electrodes. Subsequently, the growth substrate is lifted off the epitaxial structure by using the temporary sub-mount as a structural support, and the epitaxial structure is transferred to a display panel.

However, the micro LED is tiny, such that a total thickness of the epitaxial structure and the contact electrodes is usually several micrometers after the growth substrate is removed. The contact electrodes and/or the epitaxial structure are easily damaged in the process of lifting off the growth substrate and transferring the epitaxial structure, especially the contact electrodes with smaller surface areas, and resulting undesirable product yield.

Therefore, a structure for manufacturing a micro LED is needed to prevent an epitaxial structure and contact electrodes from being damaged during lifting off a growth substrate and transferring, so as to enhance yield of the micro LED.

### SUMMARY

An objective of the present disclosure is to provide a micro LED, wherein a cavity for a first electrode to contact a first semiconductor layer is distant from an edge of the micro LED. The first electrode can cover a side surface and a bottom surface of the cavity to increase a connection area between the first electrode and an epitaxial structure and to strengthen the micro LED structure, thereby enhancing yield of the micro LED.

Another objective of the present disclosure is to provide a micro LED, wherein a depth of a cavity for a first electrode being located, an area and a width of an opening of the cavity, as well as areas of the first electrode and a second electrode are designed to further increase structural strength of the micro LED.

To achieve aforementioned objectives, the present disclosure provides a micro LED including an epitaxial structure, an insulation layer, a first electrode, and a second electrode. The epitaxial structure includes a first semiconductor layer, a light-emitting layer, and a second semiconductor layer stacked in sequence. The epitaxial structure has a cavity penetrating the second semiconductor layer and the light-emitting layer and exposing a portion of the first semiconductor layer. The insulation layer covers a surface of the epitaxial structure, and a side surface and a bottom surface of the cavity. The insulation layer has a first hole exposing a portion of the second semiconductor layer, and a second hole exposing a portion of the bottom surface of the cavity. The first electrode covers the exposed portion of the bottom surface of the cavity and is connected to the first semiconductor layer. The second electrode covers the exposed portion of the second semiconductor layer. The first electrode is distant from the second electrode. The cavity is separated from an edge of the micro LED by a distance. A relation equation of the distance, and a length and a width of the micro LED is d≥2 sin(a/b), in which d represents the distance, a represents the length of the micro LED, and b represents the width of the micro LED.

In one embodiment of the present disclosure, the distance is at least 1 μm.

In one embodiment of the present disclosure, the cavity has an opening in the surface of the epitaxial structure, and an area of the opening is 3% to 25% of an area of the micro LED when viewed from a top of the micro LED.

In one embodiment of the present disclosure, a width of the opening of is 10% to 50% of the width of the micro LED.

In one embodiment of the present disclosure, a total area of the first electrode and the second electrode is equal to or greater than 30% of the area of the micro LED when viewed from the top of the micro LED.

In one embodiment of the present disclosure, the area of the opening is equal to or greater than 20% of a total area of the first electrode and the second electrode when viewed from the top of the micro LED.

In one embodiment of the present disclosure, the area of the opening is equal to or greater than 15% of an area of the first electrode or an area of the second electrode when viewed from the top of the micro LED.

In one embodiment of the present disclosure, a depth of the cavity is equal to or smaller than 25% of a combined thickness of the epitaxial structure, the insulation layer, the first electrode, and the second electrode.

In one embodiment of the present disclosure, shapes of the first electrode, the second electrode, and the opening of the cavity are circles, quadrilaterals, or polygons.

In one embodiment of the present disclosure, the micro LED further includes a temporary sub-mount. A surface of the temporary sub-mount is connected to the first electrode and the second electrode, and the surface of the temporary sub-mount is prefabricated with wires or devices coupled to the first electrode and the second electrode.

### BRIEF DESCRIPTION OF THE DRAWINGS

The aforementioned and other objectives, features, advantages, and embodiments of the present disclosure can be more fully understood by reading the following detailed description of the embodiment, with reference made to the accompanying drawings as follows:

FIG. 1 is a schematic top view of a micro LED in accordance with one embodiment of the present disclosure;

FIG. 2 is a schematic cross-sectional view of the micro LED of FIG. 1 along a line A-A;

FIG. 3 is a schematic cross-sectional view of a micro LED in accordance with one embodiment of the present disclosure;

FIG. 4 is a schematic cross-sectional view of a micro LED in accordance with one embodiment of the present disclosure; and

FIG. 5 is a schematic cross-sectional view of a micro LED in accordance with one embodiment of the present disclosure.

### DETAILED DESCRIPTION

The following disclosure provides many different embodiments for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first feature and the second feature are formed in direct contact, and may also include embodiments in which additional features may be formed between the first feature and the second feature.

Spatially relative terms, such as “beneath,” “below,” “lower,” “above,” “upper” and the like, may be used herein for ease of description to describe one element's relationship to another element(s) as illustrated in the figures. The spatially relative terms are intended to encompass different orientations of the device in use or operation in addition to the orientation depicted in the figures.

A micro LED of the present disclosure may be referred to that having a length, a width, and a height in a range from 1 m to 100 μm. For example, the length, the width, or the height of the micro LED of the present disclosure may be 20 μm, 10 μm, or 5 μm.

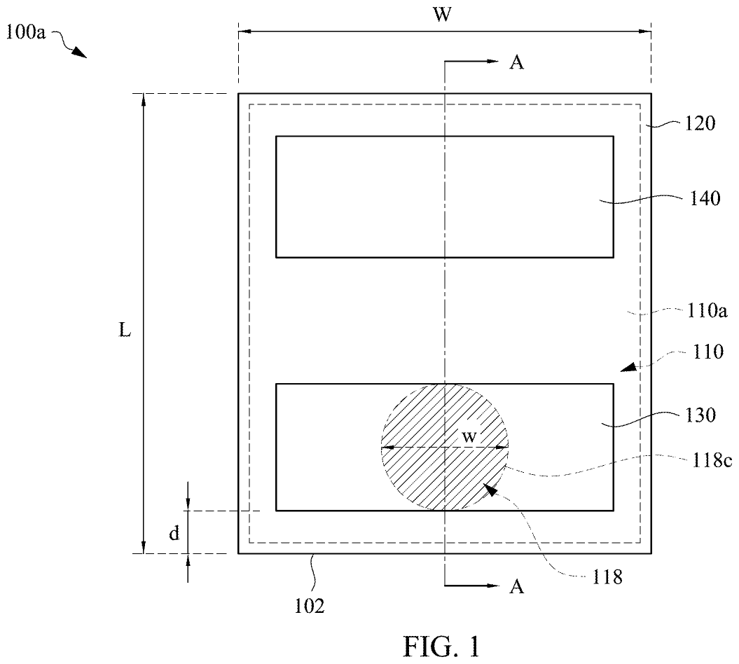

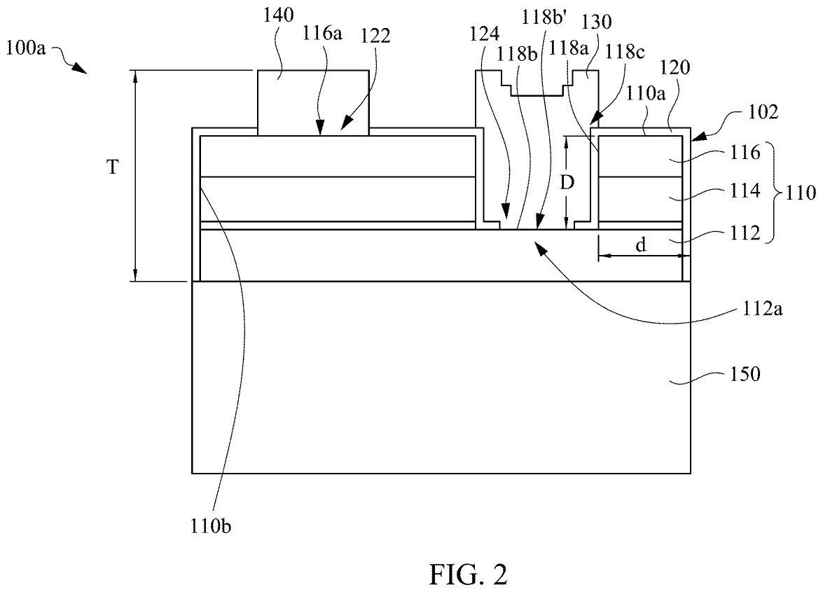

Referring to FIG. 1 and FIG. 2 simultaneously, FIG. 1 and FIG. 2 are respectively a schematic top view of a micro LED in accordance with one embodiment of the present disclosure and a schematic cross-sectional view of the micro LED of FIG. 1 along a line A-A. The micro LED 100a may mainly include an epitaxial structure 110, an insulation layer 120, a first electrode 130, and a second electrode 140. The epitaxial structure 110 may be epitaxially grown on a substrate 150. Thus, the substrate 150 is generally referred as a growth substrate. A material of the substrate 150 may be, for example, sapphire, silicon carbide (SiC), or aluminum nitride (AlN).

In some embodiments, the epitaxial structure 110 may include a first semiconductor layer 112, a light-emitting layer 114, and a second semiconductor layer 116 stacked on the substrate 150 sequentially. The first semiconductor layer 112 and the second semiconductor layer 116 have different conductive types, such as an N type and a P type. For example, the first semiconductor layer 112 is N-type, and the second semiconductor layer 116 is P-type. The light-emitting layer 114 is sandwiched between the first semiconductor layer 112 and the second semiconductor layer 116. For example, materials of the first semiconductor layer 112 and the second semiconductor layer 116 may include gallium nitride (GaN) or GaN-based materials, such as aluminum gallium nitride (AlGaN). The light-emitting layer 114 may include a multiple quantum well (MQW) structure. The light-emitting layer 114 may be formed by alternatively stacking the GaN and the GaN-based material.

In some embodiments, the epitaxial structure 110 may optionally include a buffer layer (not shown) disposed between the substrate 150 and the first semiconductor layer 112 to benefit epitaxial growth of the semiconductor layer 112 on the substrate 150. The epitaxial structure 110 may optionally include a superlattice structure (not shown) disposed between the buffer layer and the first semiconductor layer 112.

As shown in FIG. 2, the epitaxial structure 110 has a cavity 118, and the cavity 118 extends from a surface 110a of the epitaxial structure 110 to the first semiconductor layer 112 through the second semiconductor layer 116 and the light-emitting layer 114. That is the cavity 118 sequentially passes through the second semiconductor layer 116 and the light-emitting layer 114 and exposes a portion 112a of the first semiconductor layer 112. In the present embodiments, the cavity 118 is not disposed on an edge of the epitaxial structure 110. In addition, the cavity 118 is separated from an edge 102 of the micro LED 100a by a distance d, which is the smallest distance between the cavity 118 and the edge 102 of the micro LED 100a. The distance d is at least 1 g m in some embodiments.

The cavity 118 has a side surface 118a, a bottom surface 118b, and an opening 118c. The bottom surface 118b of the cavity 118 is a surface of the exposed portion 112a of the first semiconductor layer 112, and the side surface 118a extends from the first semiconductor layer 112 to the surface 110a of the epitaxial structure 110. The opening 118c of the cavity 118 is located within the surface 110a of the epitaxial structure 110. In some examples, referring to FIG. 1, a relation equation of the distance d between the cavity 118 and the edge 102 of the micro LED 100a, and a length L and a width W of the micro LED 100a is listed as a following equation (1).

d≤2 sin(a/b) equation (1)

the letter d in the equation (1) represents the distance d, the letter a represents the length L of the micro LED 100a, and the letter b represents the width W of the micro LED 100a.

In some other embodiments, as shown in FIG. 1, an area of the opening 118c of the cavity 118 is about 3% to about 25% of an area of the micro LED 100a when viewed from the top of the micro LED 100a. In other embodiments, a width w of the opening 118c of the cavity 118 is about 10% to about 50% of the width W of the micro LED 100a. In addition, the opening 118c of the cavity 118 may have any shape, such as a circle, a quadrilateral, or a polygon.

The insulation layer 120 covers the surface 110a of the epitaxial structure 110, and the side surface 118a and the bottom surface 118b of the cavity 118. In some embodiments, as shown in FIG. 2, the insulation layer 120 also extends to and covers a side surface 110b of the epitaxial structure 110, and the length L, the width W, and the area of the micro LED 100a viewed from the top all include dimensions of the insulation layer 120. The insulation layer 120 may have a first hole 122 and a second hole 124, in which the first hole 122 exposes a portion 116a of the second semiconductor layer 116, and the second hole 124 exposes a portion 118b′ of the bottom surface 118b of the cavity 118. A material of the insulation layer 120 may be, for example, silicon oxide or silicon nitride.

The first electrode 130 fills at least one portion of the cavity 118 and covers the portion 118b′ of the bottom surface 118b of the cavity 118 exposed by the second hole 124 of the insulation layer 120 to be connected to the first semiconductor layer 112, so as to electrically contact with the first semiconductor layer 112. In some embodiments, as shown in FIG. 2, the first electrode 130 fills the entire cavity 118, and covers the insulation layer 120 on the side surface 118a and the bottom surface 118b of the cavity 118 and the first semiconductor layer 112. The first electrode 130 may extend from the bottom surface 118b of the cavity 118 to the insulation layer 120 on the side surface 118a of the cavity 120 and the surface 110a of the epitaxial structure 110. A material of the first electrode 130 may include any one of Ti, Ni, Al, Pd, Rh, Pt, Au, and Cr, or an alloy thereof, for example. The first electrode 130 may have any shape, such as a circle, a quadrilateral, or a polygon.

In this embodiment, a connection area of the first electrode 130, which is directly connected to the exposed portion of the first semiconductor layer 112 in the cavity 118 and indirectly connected to the epitaxial structure 110, is apparently greater than a connection area of a conventional micro LED structure. Therefore, an adhesion force between the first electrode 130 and the epitaxial structure 110 is greatly increased. Furthermore, this embodiment increases the adhesion force of the first electrode 130 disposed in the cavity 118 to the epitaxial structure 110 while keeping electrical performance of the micro LED 100a by designing an area ratio of the opening 118c of the cavity 118 to the micro LED 100a, and/or a width ratio of the opening 118c to the micro LED 100a.

The second electrode 140 covers the portion 116a of the second semiconductor layer 116 exposed by the first hole 122 of the insulation layer 120 to be electrically connected to the second semiconductor layer 116. The second electrode 140 is distant from the first electrode 130. Similarly, a material of the second electrode 140 may, for example, include any one of Ti, Ni, Al, Pd, Rh, Pt, Au, and Cr, or an alloy thereof. The second electrode 140 may have any shape, such as a circle, a quadrilateral, or a polygon.

In some embodiments, as shown in FIG. 1, a total area of the first electrode 130 and the second electrode 140 may be equal to or greater than 30% of the area of the micro LED 100a when viewed from the top of the micro LED 100a. In other embodiments, the area of the opening 118c of the cavity 118 may be equal to or greater than 20% of the total area of the first electrode 130 and the second electrode 140 when viewed from the top of the micro LED 100a. In addition, when viewed from the top of the micro LED 100a, the area of the opening 118c of the cavity 118 may be equal to or greater than 15% of an area of the first electrode 130 or an area of the second electrode 140, for example. In some embodiments, a depth D of the cavity 118 is equal to or smaller than 25% of a combined thickness T of the epitaxial structure 110, the insulation layer 120, the first electrode 130, and the second electrode 140.

This embodiment further designs a ratio of the total area of the first electrode 130 and the second electrode 140 to the area of the micro LED 100a; ratios of the area of the opening 118c of the cavity 118 to the area of the first electrode 130, the area of the second electrode 140, and the total area of the first electrode 130 and the second electrode 140; and/or a ratio of the depth D of the cavity 118 to the combined thickness T of the epitaxial structure 110, the insulation layer 120, the first electrode 130, and the second electrode 140, to increase structural strength of the micro LED 100a.

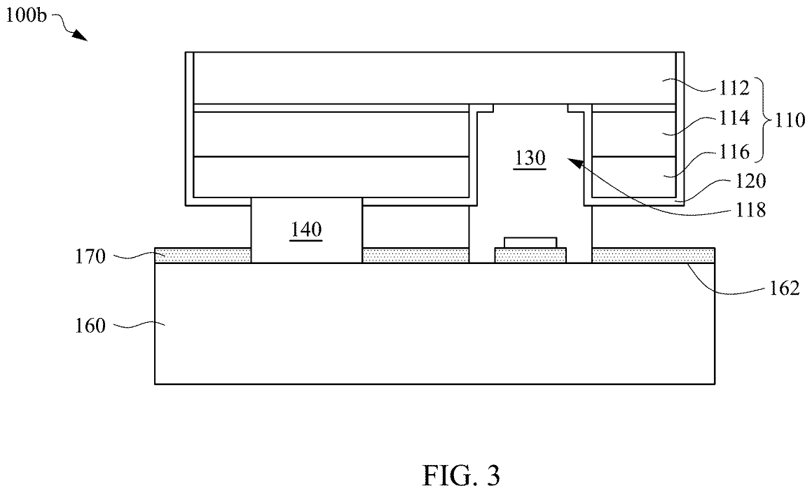

In some embodiments, the micro LED may optionally include a temporary sub-mount. Referring to FIG. 3, FIG. 3 is a schematic cross-sectional view of a micro LED in accordance with one embodiment of the present disclosure. A structure of a micro LED 100b of the present embodiment is substantially similar to that of the micro LED 100a of the aforementioned embodiment, and a difference between the micro LED 100b and the micro LED 100a is that the micro LED 100b further includes a temporary sub-mount 160. A surface 162 of the temporary sub-mount 160 is connected to the first electrode 130 and the second electrode 140.

The temporary sub-mount 160 may be any sub-mount which can provide the combination of the epitaxial structure 110, the insulation layer 120, the first electrode 130, and the second electrode 140 with structural support, to benefit the proceeding of lifting off the substrate 150 subsequently. In some embodiments, the surface 162 of the temporary sub-mount 160 may be prefabricated with wires or devices which are coupled with the first electrode 130 and the second electrode 140, such that the epitaxial structure 110 may be electrically connected to the temporary sub-mount 160 via the first electrode 130 and the second electrode 140. The surface 162 of the temporary sub-mount 160 may be optionally coated with a temporary gel 170. The first electrode 130 and the second electrode 140 penetrate the temporary gel 170 to be connected to the surface 162 of the temporary sub-mount 160. The temporary gel 170 may be any gel, such as a laser gel and polydimethylsiloxane (PDMS). In other embodiments, the surface 162 of the temporary sub-mount 160 may not include a temporary gel.

After the first electrode 130 and the second electrode 140 are connected to the surface 162 of the temporary sub-mount 160, the substrate 150 is lifted off by using the temporary sub-mount 160 as the support to substantially complete the micro LED 100b, as shown in FIG. 3. The substrate 150 may be lifted off by using a laser lift-off method. Any laser type, such as a diode-pumped solid-state laser (DPSS) or an excimer laser, can be used to remove the substrate 150. When the substrate 150 is removed by using a laser, a linear method or a stepping method may be used. In the present disclosure, when the substrate 150 is lifted off, laser process parameters, such as a laser wavelength, a pulse width, energy density, a beam spot shape, a beam spot array, laser duration, and a laser path are not limited, and material types to be separated by the laser are not limited. For example, the wavelength of the laser may be 200 nm to 400 nm.

During the laser lift-off process, the temporary gel 170 can secure the epitaxial structure 110 and various structures disposed thereon to make the substrate 150 be successfully separated from the epitaxial structure 110, and can steady the construction comprising the epitaxial structure 110 and the structures disposed thereon to prevent a crack from forming in the construction.

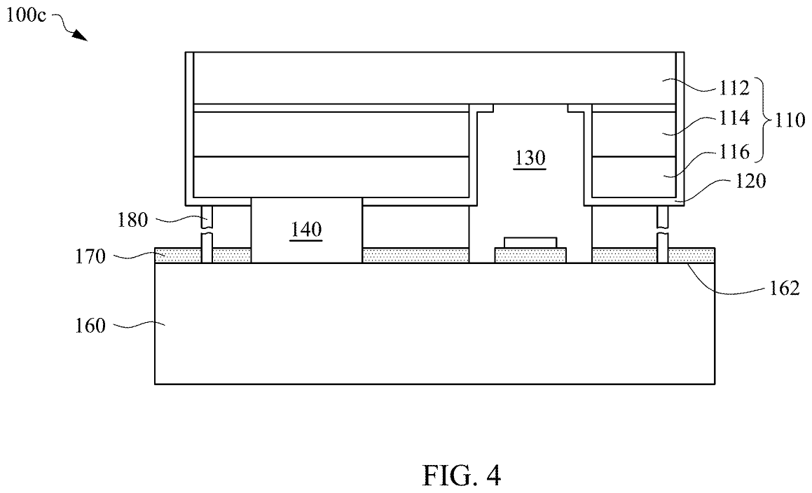

Referring to FIG. 4, FIG. 4 is a schematic cross-sectional view of a micro LED in accordance with one embodiment of the present disclosure. A structure of a micro LED 100c of the present embodiment is substantially similar to that of the micro LED 100b of the aforementioned embodiment, and a difference between the micro LED 100c and the micro LED 100b is that at least one sacrificial structure 180 is disposed between the temporary sub-mount 160 and the epitaxial structure 110 of the micro LED 100c.

When the epitaxial structure 110 is connected to the surface 162 of the temporary sub-mount 160, the sacrificial structure 180 can prop between the epitaxial structure 110 and the temporary sub-mount 160 to disperse a pressing force applied to the epitaxial structure 110, so as to effectively prevent the epitaxial structure 110 and/or the structure layers disposed thereon from being split or separated. In some embodiments, after the epitaxial structure 110 is pressed on the surface 162 of the temporary sub-mount 160, the sacrificial structure 180 may be fractured. The sacrificial structure 180 may be in any shape and any form. For example, the sacrificial structure 180 may be a post structure.

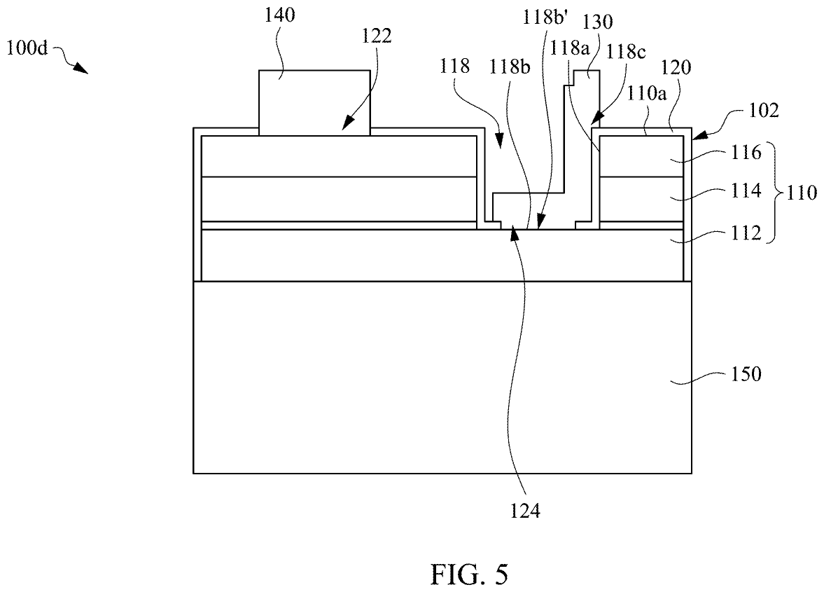

The disposition of the first electrode in the cavity of the epitaxial structure of the present disclosure can be different from that of the embodiment shown in FIG. 2. Referring to FIG. 5, FIG. 5 is a schematic cross-sectional view of a micro LED in accordance with one embodiment of the present disclosure. A structure of a micro LED 100d of the present embodiment is substantially similar to that of the micro LED 100a in FIG. 2, and a difference between the micro LED 100d and the micro LED 100a is that a first electrode 130a of the micro LED 100d does not fill up the cavity 118.

In the micro LED 100d, the first electrode 130a similarly covers the portion 118b′ of the bottom surface 118b of the cavity 118 exposed by the second hole 124 of the insulation layer 120, but only fills a portion of the cavity 118. In addition, the first electrode 130a extends from the bottom surface 118b of the cavity 118 and covers the insulation layer 120 on the side surface 118a of the cavity 118 and the surface 110a of the epitaxial structure 110. Thus, a connection area between the first electrode 130a and the epitaxial structure 110 can be also increased.

According to the aforementioned embodiments, one advantage of the present disclosure is that a cavity for a first electrode of a micro LED to contact a first semiconductor layer is distant from an edge of the micro LED. The first electrode can cover a side surface and a bottom surface of the cavity to increase a connection area between the first electrode and an epitaxial structure and to strengthen the micro LED structure, thereby enhancing yield of the micro LED.

According to the aforementioned embodiments, another advantage of the present disclosure is that the present disclosure designs a depth of a cavity for a first electrode being located, as well as an area and a width of an opening of the cavity, areas of the first electrode and a second electrode to further increase structural strength of a micro LED.

Although the present invention has been described in considerable details with reference to certain embodiments, the foregoing embodiments of the present invention are illustrative of the present invention rather than limiting of the present invention. It will be apparent to those having ordinary skill in the art that various modifications and variations can be made to the present invention without departing from the scope or spirit of the invention. Therefore, the spirit and scope of the appended claims should not be limited to the description of the embodiments contained herein.

What is claimed is:

1. A micro light-emitting diode, comprising:
an epitaxial structure comprising a first semiconductor layer, a light-emitting layer, and a second semiconductor layer stacked in sequence, wherein the epitaxial structure has a cavity penetrating the second semiconductor layer and the light-emitting layer and exposing a portion of the first semiconductor layer;
an insulation layer covering a surface of the epitaxial structure, and a side surface and a bottom surface of the cavity, wherein the insulation layer has a first hole exposing a portion of the second semiconductor layer, and a second hole exposing a portion of the bottom surface of the cavity;
a first electrode covering the exposed portion of the bottom surface of the cavity and connected to the first semiconductor layer; and
a second electrode covering the exposed portion of the second semiconductor layer, wherein the first electrode is distant from the second electrode,
wherein the cavity is separated from an edge of the micro light-emitting diode by a distance, and a relation equation of the distance, and a length and a width of the micro light-emitting diode is:
d≤2 sin(a/b),
wherein d represents the distance, a represents the length of the micro light-emitting diode, and b represents the width of the micro light-emitting diode.

2. The micro light-emitting diode of claim 1, wherein the distance is at least 1 μm.

3. The micro light-emitting diode of claim 1, wherein the cavity has an opening in the surface of the epitaxial structure, and an area of the opening is 3% to 25% of an area of the micro light-emitting diode when viewed from a top of the micro light-emitting diode.

4. The micro light-emitting diode of claim 3, wherein a width of the opening of is 10% to 50% of the width of the micro light-emitting diode.

5. The micro light-emitting diode of claim 3, wherein a total area of the first electrode and the second electrode is equal to or greater than 30% of the area of the micro light-emitting diode when viewed from the top of the micro light-emitting diode.

6. The micro light-emitting diode of claim 3, wherein the area of the opening is equal to or greater than 20% of a total area of the first electrode and the second electrode when viewed from the top of the micro light-emitting diode.

7. The micro light-emitting diode of claim 6, wherein the area of the opening is equal to or greater than 15% of an area of the first electrode or an area of the second electrode when viewed from the top of the micro light-emitting diode.

8. The micro light-emitting diode of claim 1, wherein a depth of the cavity is equal to or smaller than 25% of a combined thickness of the epitaxial structure, the insulation layer, the first electrode, and the second electrode.

9. The micro light-emitting diode of claim 1, wherein shapes of the first electrode, the second electrode, and the opening of the cavity are circles, quadrilaterals, or polygons.

10. The micro light-emitting diode of claim 1, further comprising a temporary sub-mount, wherein a surface of the temporary sub-mount is connected to the first electrode and the second electrode, and the surface of the temporary sub-mount is prefabricated with wires or devices coupled to the first electrode and the second electrode.

11. A micro light-emitting diode, comprising:
an epitaxial structure comprising a first semiconductor layer, a light-emitting layer, and a second semiconductor layer stacked in sequence, wherein the epitaxial structure has a cavity penetrating the second semiconductor layer and the light-emitting layer and exposing a portion of the first semiconductor layer, the cavity is separated from an edge of the micro light-emitting diode by a distance, and the distance is not zero, wherein the cavity has an opening in a surface of the epitaxial structure, and an area of the opening is 3% to 25% of an area of the micro light-emitting diode when viewed from a top of the micro light-emitting diode;
an insulation layer covering the surface of the epitaxial structure, and a side surface and a bottom surface of the cavity, wherein the insulation layer has a first hole exposing a portion of the second semiconductor layer, and a second hole exposing a portion of the bottom surface of the cavity;
a first electrode covering the exposed portion of the bottom surface of the cavity and connected to the first semiconductor layer; and
a second electrode covering the exposed portion of the second semiconductor layer, wherein the first electrode is distant from the second electrode.

12. The micro light-emitting diode of claim 11, wherein the distance is at least 1 μm.

13. The micro light-emitting diode of claim 11, wherein a width of the opening of is 10% to 50% of the width of the micro light-emitting diode.

14. The micro light-emitting diode of claim 11, wherein a total area of the first electrode and the second electrode is equal to or greater than 30% of the area of the micro light-emitting diode when viewed from the top of the micro light-emitting diode.

15. The micro light-emitting diode of claim 11, wherein the area of the opening is equal to or greater than 20% of a total area of the first electrode and the second electrode when viewed from the top of the micro light-emitting diode.

16. The micro light-emitting diode of claim 11, wherein a depth of the cavity is equal to or smaller than 25% of a combined thickness of the epitaxial structure, the insulation layer, the first electrode, and the second electrode.

17. A micro light-emitting diode, comprising:
an epitaxial structure comprising a first semiconductor layer, a light-emitting layer, and a second semiconductor layer stacked in sequence, wherein the epitaxial structure has a cavity penetrating the second semiconductor layer and the light-emitting layer and exposing a portion of the first semiconductor layer, the cavity is separated from an edge of the micro light-emitting diode by a distance, and the distance is not zero;
an insulation layer covering a surface of the epitaxial structure, and a side surface and a bottom surface of the cavity, wherein the insulation layer has a first hole exposing a portion of the second semiconductor layer, and a second hole exposing a portion of the bottom surface of the cavity;
a first electrode covering the exposed portion of the bottom surface of the cavity and connected to the first semiconductor layer; and
a second electrode covering the exposed portion of the second semiconductor layer, wherein the first electrode is distant from the second electrode,
wherein a depth of the cavity is equal to or smaller than 25% of a combined thickness of the epitaxial structure, the insulation layer, the first electrode, and the second electrode.

18. The micro light-emitting diode of claim 17, wherein the distance is at least 1 μm, and a width of the opening of is 10% to 50% of the width of the micro light-emitting diode.

19. The micro light-emitting diode of claim 17, wherein the first electrode extends from the bottom surface of the cavity to the insulation layer on the side surface of the cavity and the surface of the epitaxial structure.

20. The micro light-emitting diode of claim 17, wherein the area of the opening is equal to or greater than 20% of a total area of the first electrode and the second electrode when viewed from a top of the micro light-emitting diode.
